(19) United States
(12) Patent Application Publication
(10) Pub. No.: US 2019/0229709 A1
(43) Pub. Date: Jul. 25, 2019

(54) SWITCHED-CAPACITOR FILTER WITH GLITCH REDUCTION

(71) Applicant: TEXAS INSTRUMENTS INCORPORATED, Dallas, TX (US)

(72) Inventors: Amit Kumar GUPTA, Frisco, TX (US); Peng CAO, Richardson, TX (US)

(21) Appl. No.: 16/046,581

(22) Filed: Jul. 26, 2018

Related U.S. Application Data
(60) Provisional application No. 62/620,048, filed on Jan. 22, 2018.

(51) Int. Cl. H03H 19/00

(52) U.S. Cl. CPC H03H 19/004; H03M 1/66

(57) ABSTRACT

An apparatus includes a switched-capacitor filter. The switched-capacitor filter includes an integrator and a feedback loop between an output node of the integrator and an input node of the integrator, wherein the feedback loop includes a feedback capacitor, a first switch, and a second switch. The switched-capacitor filter also includes a pre-charge path between the output node of the integrator and the feedback capacitor, wherein the pre-charge path includes a pre-charge buffer and a third switch.

### CROSS-REFERENCE TO RELATED APPLICATIONS

The present application claims priority to U.S. Provisional Patent Application No. 62/620,048, filed Jan. 22, 2018, titled “Low Glitch Switched Capacitor DAC and Filter with Improved Distortion Performance,” which is hereby incorporated herein by reference in its entirety.

### BACKGROUND

Different electrical systems or different components within an electrical system operate on analog signals or digital signals. Also, switching back and forth between analog and digital signals is common practice (e.g., to perform discrete-time signal processing). One example operation that is performed on analog or digital signals is referred to as “filtering.” In electrical circuits, “filtering” refers to altering the amplitude and/or phase characteristics of a signal with respect to frequency. Ideally, filtering does not add new frequencies to the input signal, nor change the component frequencies of the input signal. In some scenarios, filtering changes the relative amplitudes of the various frequency components and/or their phase relationships. Filtering is often used in electronic systems to emphasize signals in certain frequency ranges and reject signals in other frequency ranges.

Many different filter designs have been used in electronic systems to perform filtering. One example filter used in modern electronics is an active filter circuit that includes an op amp with a resistor and a capacitor in its feedback loop. Another example filter used in modern electronics is a switched-capacitor filter. Switched-capacitor filters are clocked, sampled-data systems, where the input signal is sampled at a high rate and is processed on a discrete-time, rather than continuous, basis. The operation of switched-capacitor filters is based on the ability of on-chip capacitors and transistor-based switches to simulate resistors. By closely matching the values of on-chip capacitors for a switched-capacitor filters to other capacitors of an integrated circuit, the cutoff frequencies for the filter are proportional to, and determined only by, an external clock frequency.

Some benefits of switched-capacitor filters (compared to active filter circuits) include avoidance/reduction of resistors, repeatable filter designs using inexpensive crystal-controlled oscillators, and/or cutoff frequencies that are variable over a wide range simply by changing an external clock frequency. In addition, at least some switched-capacitor filters have low sensitivity to temperature changes.

### SUMMARY

In accordance with at least one example of the disclosure, an apparatus comprises a switched-capacitor filter. The switched-capacitor filter comprises an integrator and a feedback loop between an output node of the integrator and an input node of the integrator. The feedback loop includes a feedback capacitor and a first switch, and a second switch. The switched-capacitor filter also comprises a pre-charge path between the output node of the integrator and the feedback capacitor. The pre-charge path includes a pre-charge buffer and a third switch. During a first portion of an integration phase, the first and second switches are open and the third switch is closed. During a second portion of the integration phase, the first and second switches are closed and the third switch is open.

In accordance with at least one example of the disclosure, a switched-capacitor filter comprises an integrator and a feedback loop between an output node of the integrator and an input node of the integrator. The switched-capacitor filter also comprises a de-glitch circuit integrated with the feedback loop. The de-glitch circuit comprises a pre-charge buffer configured to provide a charge to a feedback capacitor in the feedback loop during part of an integration phase of the integrator.

In accordance with at least one example of the disclosure, a switched-capacitor filter method comprises receiving an integration phase signal. In response to the integration phase signal, a pre-charge buffer is used to charge a feedback capacitor during a first portion of an integration phase associated with the integration phase signal. The method also comprises coupling the feedback capacitor between input and output nodes of an integrator during a second portion of the integration phase.

### BRIEF DESCRIPTION OF THE DRAWINGS

For a detailed description of various examples, reference will now be made to the accompanying drawings in which:

FIG. 1 shows a block diagram of a device having a switched-capacitor filter with glitch reduction in accordance with various examples;

FIG. 2 shows a schematic diagram of circuitry including a switched-capacitor filter circuit in accordance with various examples;

FIG. 3 shows a timing diagram of control signals for the circuitry of FIG. 2 in accordance with various examples;

FIG. 4 shows a block diagram of device having the circuitry of FIG. 2 in accordance with various examples; and

FIG. 5 shows a switch-capacitor filter method in accordance with various examples.

### DETAILED DESCRIPTION

The disclosed examples are directed to switched-capacitor filters with glitch reduction and related topologies, devices, and methods. An example switched-capacitor filter topology includes an integrator and a feedback loop between an output node of the integrator and an input node of the integrator, where the feedback loop includes a feedback capacitor and two switches (one switch to each side of the feedback capacitor). The example switched-capacitor filter topology also includes a pre-charge path between the output node of the integrator and the feedback capacitor, where the pre-charge path includes a pre-charge buffer and a third switch. During a first portion of an integration phase, the first and second switches are open and the third switch is closed. During a second portion of the integration phase, the first and second switches are closed and the third switch is open. Using a pre-charge buffer to charge the feedback capacitor during a first portion of the integration phase as described herein reduces glitches at the output of a switched-capacitor filter. To provide a better understanding, various switched-capacitor filter circuitry, device, and method options are described using the figures as follows.

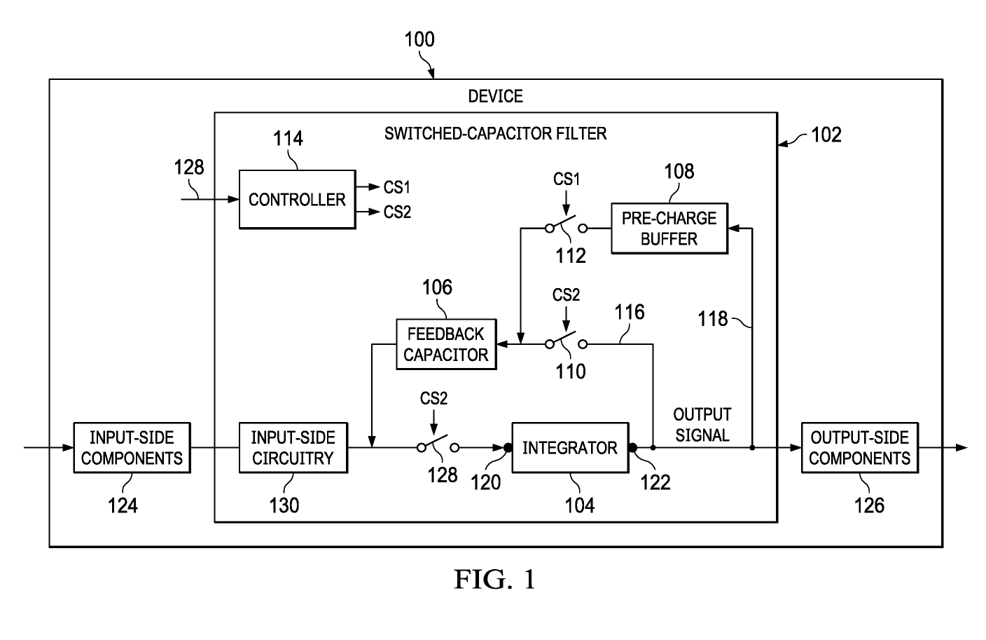

FIG. 1 shows a block diagram of a device 100 having a switched-capacitor filter 102 with glitch reduction in accordance with various examples. As shown in FIG. 1, the switched-capacitor filter 102 comprises an integrator 104, which is formed by putting an integrating capacitor around an operational amplifier. Also, there is a feedback loop 116 between an input node 120 and an output node 122 of the integrator 104, where the feedback loop 116 includes a feedback capacitor 106, a switch 110 (a first switch of the switched-capacitor filter 102) and a switch 128 (a second switch of the switched-capacitor filter 102). The switched-capacitor filter 102 also includes a pre-charge path 118 between the feedback capacitor 106 and the output node 122 of the integrator 104, where the pre-charge path 118 includes a pre-charge buffer 108 and a switch 112 (a third switch of the switched-capacitor filter 102).

In some examples, the switches 110 and 128 of the feedback loop 116 are controlled by a control signal (CS2). Meanwhile, the switch 112 of the pre-charge path 118 is controlled by another control signal (CS1). In some examples, CS1 and CS2 are provided by a controller 114. In some examples, the timing of CS1 and CS2 is determined by the controller 114 (e.g., the controller 114 is programmed to direct the operations of the switches 110, 128, and 112 based on a predetermined routine for the switched-capacitor filter 102). In other examples, the controller 114 receives one or more input signals 128, where the timing of CS1 and CS2 are based at least in part on the one or more input signals 128 (e.g., the one or more input signals 128 indicate when a sampling phase begins or ends).

As previously noted, the switched-capacitor filter 102 is part of a device 100. In different examples, the device 100 includes one or more integrated circuits, unpackaged or packaged dies, and/or discrete components. In the example of FIG. 1, the device 100 includes input-side components 124 and output-side components 124 relative to the switched-capacitor filter 102. In some examples, the switched-capacitor filter 102 includes input-side circuitry 130 between the input-side components 124 of the device 100 and other components of the switched-capacitor filter 102. In one example, the input-side circuitry 130 corresponds to at least one capacitor and switches.

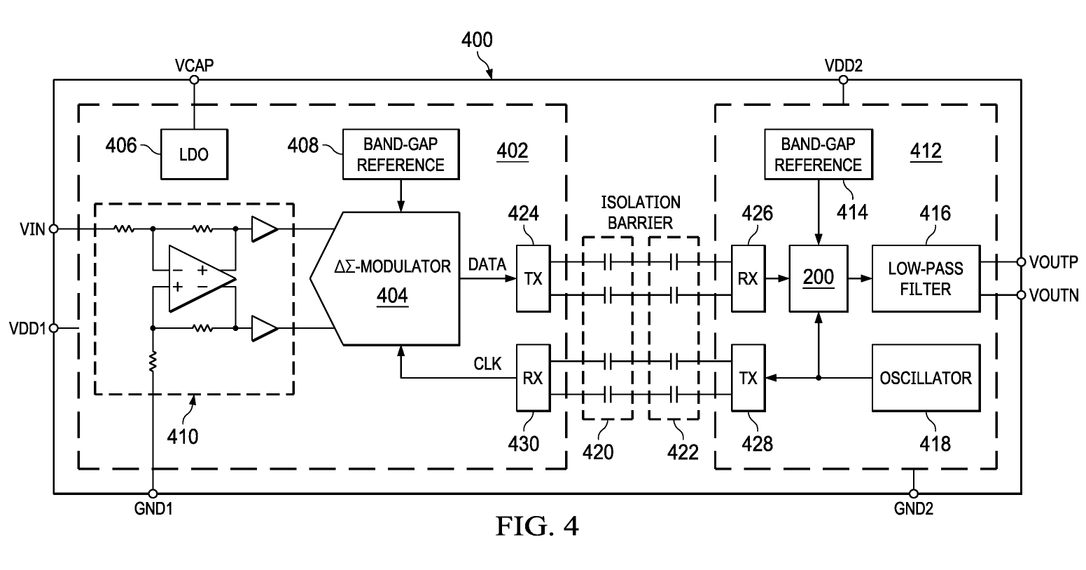

In some examples, the device 100 corresponds to an isolated amplifier. In such case, examples of the input-side components 124 include isolation circuitry, transmitter circuitry, receiver circuitry, and/or digital-to-analog converter (DAC) circuitry (see e.g., FIG. 4). Meanwhile, examples of the output-side components 126 include a low-pass filter. In different examples of the device 100, input-side components 124 vary and/or are omitted. Likewise, in different examples of the device 100, the output-side components 124 vary and/or are omitted.

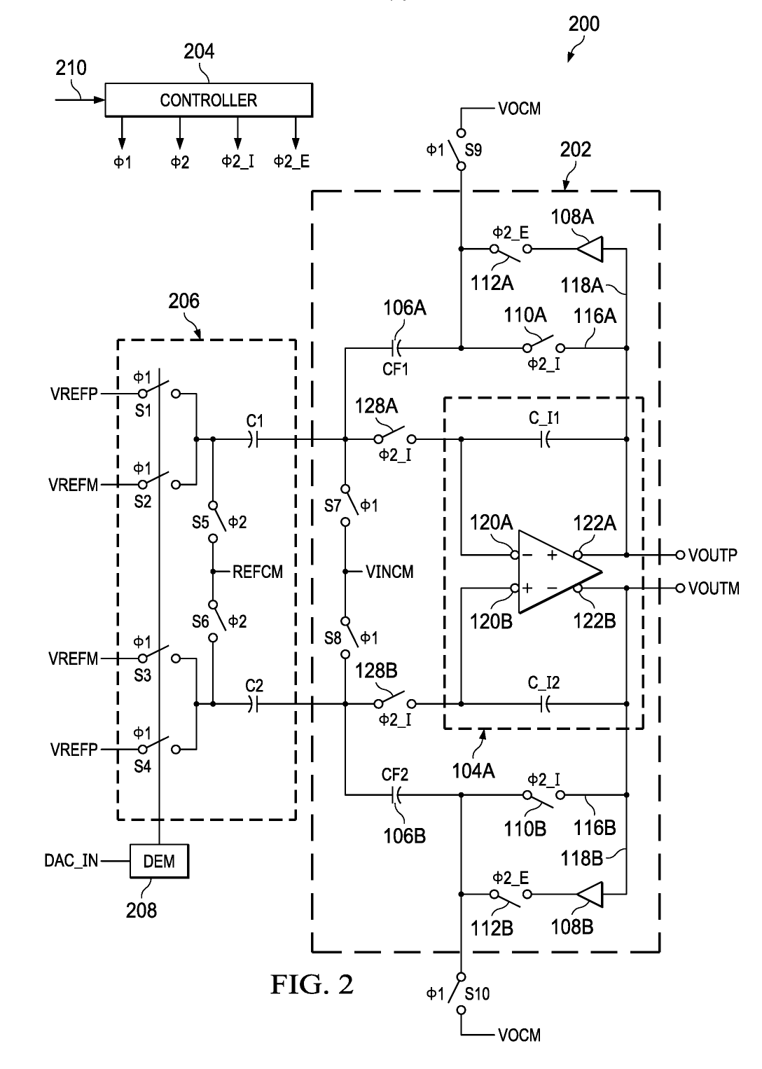

FIG. 2 shows a schematic diagram of circuitry 200 including a switched-capacitor filter circuit 202 (an example of the switched-capacitor filter 102 in FIG. 1) in accordance with various examples. In the example of FIG. 2, the switched-capacitor filter circuit 202 is designed for a differential signal scenario. Accordingly, the integrator 104A (an example of the integrator 104 in FIG. 1) has a first pair of input and output nodes 120A, 122A (an example of nodes 120 and 122 in FIG. 1), and second pair of input and output nodes 120B, 122B (another example of nodes 120 and 122 in FIG. 1). As shown in FIG. 2, there is a feedback loop 116A (an example of the feedback loop 116 in FIG. 1) and a pre-charge path 118A (an example of the pre-charge path 118 in FIG. 1) between the first pair of input and output nodes 120A and 122A. The feedback loop 116A comprises a feedback capacitor 106A labeled “CF1” (an example of the feedback capacitor 106 in FIG. 1). The feedback loop 116A also includes a switch 110A (an example of the switch 110 in FIG. 1, or first switch of the switched-capacitor filter circuit 202) and a switch 128A (an example of the switch 128 in FIG. 1, or second switch of the switched-capacitor filter circuit 202) directed by a control signal, ϕ2_I (an example of CS2 in FIG. 1, and corresponding to a second portion of an integration phase). Meanwhile, the pre-charge path 118A comprises a pre-charge buffer 108A (an example of the pre-charge buffer 108 in FIG. 1) and a switch 112A (an example of the switch 112 in FIG. 1, or third switch of the switched-capacitor filter circuit 202) directed by a control signal ϕ2_E (an example of CS1 in FIG. 1, and corresponding to a first portion of an integration phase).

As shown in FIG. 2, there is also another feedback loop 116B (another example of the feedback loop 116 in FIG. 1) and a respective pre-charge path 1186 (an example of the pre-charge path 118 in FIG. 1) between the second pair of input and output nodes 120B and 122B. The feedback loop 116B comprises a feedback capacitor 106B labeled “CF2” (an example of the feedback capacitor 106 in FIG. 1), switch 1106 (an example of the switch 110 in FIG. 1, or fourth switch of the switched-capacitor filter circuit 202), and switch 128B (an example of the switch 128 in FIG. 1, or fifth switch of the switched-capacitor filter circuit 202) directed by ϕ2_I. Meanwhile, the pre-charge path 118B comprises a pre-charge buffer 108B (an example of the pre-charge buffer 108 in FIG. 1) and a switch 112B (an example of the switch 112 in FIG. 1, or sixth switch of the switched-capacitor filter circuit 202) directed by ϕ2_E.

In the example circuitry 200 of FIG. 2, the input signals to the switched-capacitor filter 202 are provided by a DAC 206 (e.g., a 2^{N} level DAC). As shown, the DAC 206 comprises various switches, S1-S6, and capacitors, C1 and C2. More specifically, S1 selectively couples C1 to a first reference signal (VREFP), where S1 is directed by a control signal, ϕ1 (corresponding to a sampling phase). S2 selectively couples C1 to a second reference signal (VREFM), where S2 is directed by ϕ1. S3 selectively couples C2 to VREFM, where S3 is directed by ϕ1. S4 selectively couples C2 to VREFP, where S4 is directed by ϕ1. S5 selectively couples C1 to a common mode reference signal (REFCM), where S5 is directed by a control signal, ϕ2 (corresponding to an integration phase). S6 selectively couples C2 to REFCM, where S6 is directed by ϕ2. In different examples, the components represented for the DAC 206 are replicated (depending on whether DAC 206 is a 2¹ level DAC, a 2² level DAC, a 2³ level DAC, and so on). Also, in some examples, operations of the DAC 206 are based in part on dynamic element matching (DEM) operations provided by DEM circuitry 208.

In some examples, the switched-capacitor filter 202 of FIG. 2 also comprises additional switches, S7 and S8, that couple C1, C2, CF1, and CF2 to a bias voltage (VINCM), where S7 and S8 are directed by ϕ1. In FIG. 2, the switches 128A and 128B are directed by ϕ2_I to selectively couple C1, C2, CF1, and CF2 to respective input nodes 120A and 120B. In some examples, CF1 also selectively couples to a common mode signal (VOCM) via a switch, S9, directed by ϕ1. Similarly, CF2 selectively couples to VOCM via a switch, S10, directed by ϕ1.

In some examples, the control signals ϕ1, ϕ2, ϕ2_I, ϕ2_E for the various switches (e.g., S1-S10, and switches 110A, 1106, 112A, 112B, 128A, and 128B) in the circuitry 200 are generated by a controller 204. The controller 204, for example, either stores instructions regarding the timing for ϕ1, ϕ2, ϕ2_I, and ϕ2_E, and/or dynamically adjusts the timing for ϕ1, ϕ2, ϕ2_I, and ϕ2_E based on one or more control signals 210. In other circuitry that includes the switched-capacitor filter circuit 202, the DAC 206 is omitted. In such case, the switched-capacitor filter circuit 202 receives differential analog inputs, for example, from switches directed by ϕ1.

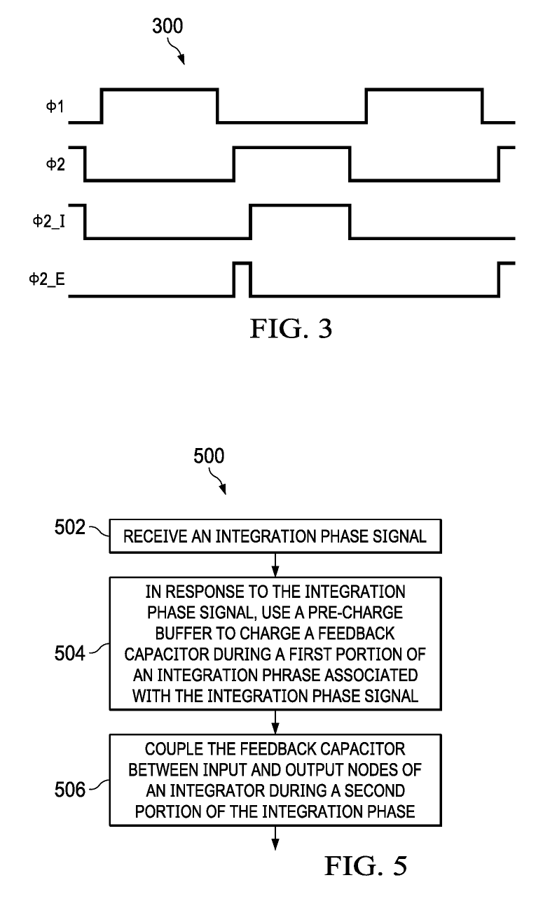

FIG. 3 shows a timing diagram 300 of control signals for the circuitry 200 of FIG. 2 in accordance with various examples. In the timing diagram 300, waveforms corresponding to the control signals ϕ1, ϕ2, ϕ2_I, and ϕ2_E are represented. In at least some examples, ϕ1 corresponds to a sampling phase, ϕ2 corresponds to an integration phase, ϕ2_E corresponds to a first portion of the integration phase (a pre-charge portion), and ϕ2_I corresponds to a second portion of the integration phase.

As shown, the “on” state (when a switch is closed) for ϕ1 does not overlap with the “on” state for any of ϕ2, ϕ2_I, and ϕ2_E. Also, the “on” state for ϕ2_E and ϕ2_I overlaps with the “on” state for ϕ2. More specifically, the “on” state for ϕ2_E overlaps with a first portion of the “on” state for ϕ2, and the “on” state for ϕ2_I overlaps with a second portion of the “on” state for ϕ2. The “on” state of ϕ2_I and ϕ2_E are non-overlapping. During ϕ2_E, a pre-charge buffer (e.g., pre-charge buffer 108A or 108B) charges a feedback capacitor (e.g., feedback capacitor 106A or 106B). During ϕ2_I, the pre-charge buffer is decoupled from the feedback capacitor, and the feedback capacitor is coupled to the input node (e.g., input nodes 120A or 120B) of an integrator (e.g., the integrator 104A) for a switched-capacitor filter circuit (e.g., the switched capacitor filter circuit 202). In some examples, the duration of the “on” state for ϕ2_E is smaller than the duration of the “on” state for ϕ2_I.

FIG. 4 shows a block diagram of device 400 having the circuitry 200 of FIG. 2 in accordance with various examples. Without limitation to other device examples, the device 400 of FIG. 4 represents an isolated amplifier. In other examples, the circuitry 200 and/or the switched-capacitor filter circuit 202 represented in FIG. 2 are included with other devices. In some device examples, a switched-capacitor filter (e.g., the switched-capacitor filter 102 in FIG. 1 or the switched-capacitor filter circuit 202 in FIG. 2) is part of an integrated circuit and/or a multi-die module.

In the example device 400 of FIG. 4, a first die 402 with a delta-sigma modulator 404 that digitizes an input signal (VIN) is represented. As desired, VIN is amplified and/or buffered by block 410 before being input to the delta-sigma modulator 404. In at least some examples, the operations of the delta-sigma modulator 404 are based on a reference voltage provided by a band-gap reference circuit 408. The output of the delta-sigma modulator 404 is provided to the circuitry 200 via a transmitter (TX) 424, isolation circuitry 420 (e.g., an isolation capacitor for each transmission line), isolation circuitry 422 (e.g., an isolation capacitor for each transmission line), and a receiver (RX) 426, where the transmitter 424 is part of the first die 402 and the receiver 426 is part of a second die 412. Other components such as a low dropout regulator (LDO) 406 and a receiver 430 are also included with the first die 402.

The second die 412 includes the circuitry 200, which performs DAC and switched-capacitor filter operations on data received from the first die 402 via the transmitter 424, the isolation circuitry 420, the isolation circuitry 422, and the receiver 426. In some examples, the operations of the circuitry 200 are based in part on a reference voltage provided by a band-gap reference circuit 414. The band-gap reference circuit 414 creates the signals VREFP and VREFM. The operation of circuitry 200 are also based on the oscillator 418, which is used to generate clock signals to control the various switches of the circuitry 200. In some examples, the output of the circuitry 200 is provided to a low-pass filter (e.g., a 4th order action low-pass filter) 416. The oscillator 418 also provides a signal (e.g., a clock signal) to the first die 402 via transmitter 428, isolation circuitry 422 (e.g., an isolation capacitor for each transmission line), isolation circuitry 420 (e.g., an isolation capacitor for each transmission line), and receiver 430. At the first die 402, the sigma-delta modulator 404 uses the signal from the oscillator 418 of the second die 412 to update its operations. As represented in FIG. 4, in at least some examples, the transmitter 428 is part of the second die 412, the receiver is part of the first die 402, and the isolation circuitry 420 and 422 is separate from the first and second dies 402 and 412.

In some examples, the first die 402 has a first voltage supply level (VDD1) and a first ground level (GND1), while the second die 412 has a second voltage supply level (VDD2) and a second ground level (GND2). In different examples, the values for VDD1 and VDD2 vary. Likewise, in different examples, the values for GND1 and GND2 vary. Accordingly, the isolation circuitry 420 and 422 enable signaling between the first and second dies 402 and 412 while protecting their respective components. In some examples, the isolation circuitry 420 and the isolation circuitry 422 correspond to dies separate from the first and second dies 402 and 412. In one example, the device 400 represented in FIG. 4 is a multi-die module having the first die 402 with the delta-sigma modulator 404, the second die 412 with the switched-capacitor filter circuit 202, a third die with the isolation circuitry 420, and a fourth die with the isolation circuitry 422.

FIG. 5 shows a switched-capacitor filter method 500 in accordance with various examples. As shown, the method 500 comprises receiving an integration phase signal (e.g., ϕ2) at block 502. In response to the integration phase signal, a pre-charge buffer (e.g., the pre-charge buffer 108 in FIG. 1) is used to charge a feedback capacitor (e.g., the feedback capacitor 106 in FIG. 1) during a first portion of an integration phase associated with the integration phase signal at block 504. In some examples, the operations of block 504 involve directing a pre-charge switch (e.g., switch 112 in FIG. 1, or switches 112A and 112B in FIG. 2) based on a control signal (e.g., CS1 or ϕ2_E). At block 506, the feedback capacitor is coupled between input and output nodes of an integrator (e.g., nodes 120 and 122 of the integrator 104 in FIG. 1) during a second portion of the integration phase. In some examples, the operations of block 506 involve directing feedback loop switches (e.g., switches 110 and 128 in FIG. 1, or switches 110A, 1106, 128A, 128B in FIG. 2) based on a control signal (e.g., CS2 or ϕ2_E). In some examples, the first and second control signals used to direct switches in blocks 504 and 504 do not overlap. Also, in some examples, the integration phase signal is separate from the first and second control signals (e.g., ϕ2 is separate from ϕ2_E and ϕ2_I). Also, in some examples, the integration phase signal (e.g., ϕ2) does not overlap with a sampling phase (e.g., ϕ1) for a DAC (e.g., the DAC 206) configured to provide an input signal to the integrator (e.g., integrator 104).

Certain terms have been used throughout this description and claims to refer to particular system components. As one skilled in the art will appreciate, different parties may refer to a component by different names. This document does not intend to distinguish between components that differ in name but not function. In this disclosure and claims, the terms “including” and “comprising” are used in an open-ended fashion, and thus should be interpreted to mean “including, but not limited to . . . .” Also, the term “couple” or “couples” is intended to mean either an indirect or direct wired or wireless connection. Thus, if a first device couples to a second device, that connection may be through a direct connection or through an indirect connection via other devices and connections. The recitation “based on” is intended to mean “based at least in part on.” Therefore, if X is based on Y, X may be a function of Y and any number of other factors.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An apparatus that comprises:
a switched-capacitor filter comprising:
an integrator;
a feedback loop between an output node of the integrator and an input node of the integrator, wherein the feedback loop includes a feedback capacitor, a first switch, and a second switch; and
a pre-charge path between the output node of the integrator and the feedback capacitor, wherein the pre-charge path includes a pre-charge buffer and a third switch.

2. The apparatus of claim 1, further comprising a controller configured to provide control signals to open the first and second switches and to close the third switch during a first portion of an integration phase, and to close the first and second switches and to open the third switch during a second portion of the integration phase.

3. The apparatus of claim 1, wherein the integrator is a differential integrator, wherein the input node and the output node correspond to a first input and output node pair, wherein the integrator comprises a second input and output node pair, wherein the feedback loop comprises a first feedback loop, wherein the feedback capacitor comprises a first feedback capacitor, wherein the pre-charge path comprises a first pre-charge path, wherein the pre-charge buffer is a first pre-charge buffer, wherein the apparatus comprises a second feedback loop between the second input and output node pair, and wherein the apparatus comprises a second pre-charge path with a second pre-charge buffer between the second output node of the integrator and a second feedback capacitor in the second feedback loop.

4. The apparatus of claim 3, wherein the second feedback loop includes a fourth switch to one side of the second feedback capacitor and a fifth switch to the other side of the second feedback capacitor, wherein the second pre-charge path includes a sixth switch,
wherein the apparatus further comprises a controller configured to provide controls signals to open the fourth and fifth switches and to close the sixth switch during a first portion of an integration phase, and to close the fourth and fifth switches and to open the sixth switch during a second portion of an integration phase.

5. The apparatus of claim 1, further comprising a digital-to-analog converter (DAC) coupled to the switched-capacitor filter and configured to provide an input signal to the switched-capacitor filter.

6. The apparatus of claim 5, further comprising a sampling circuit between the DAC and switched-capacitor filter, wherein a sampling phase and the integration phase do not overlap.

7. The apparatus of claim 1, wherein the first portion of the integration phase is smaller than the second portion of the integration phase.

8. The apparatus of claim 1, wherein the apparatus comprises an isolated amplifier that includes the switched-capacitor filter on its output side.

9. The apparatus of claim 8, wherein the isolated amplifier corresponds to a multi-die module with a die that includes the switched-capacitor filter and at least one die with isolation circuitry.

10. The apparatus of claim 1, wherein the switched-capacitor filter is part of an integrated circuit.

11. A switched-capacitor filter that comprises:
an integrator;
a feedback loop between an output node of the integrator and an input node of the integrator; and
a de-glitch circuit integrated with the feedback loop, wherein the de-glitch circuit comprises a pre-charge buffer configured to provide a charge to a feedback capacitor in the feedback loop during part of an integration phase of the integrator.

12. The switched-capacitor filter of claim 11, wherein the de-glitch circuit further comprises:
a switch in series with the pre-charge buffer; and
a controller to close the switch during a first portion of the integration phase.

13. The switched-capacitor filter of claim 11, wherein the integrator is a differential integrator, wherein the input node and the output node correspond to a first input and output node pair, wherein the feedback loop corresponds to a first feedback loop, wherein the integrator comprises a second input and output node pair, wherein the switched-capacitor filter comprises a second feedback loop between the second input and output node pair, wherein the de-glitch circuit is integrated with the first and second feedback loops, wherein the pre-charge buffer is a first pre-charge buffer, wherein the feedback capacitor is a first feedback capacitor, and wherein the de-glitch circuit comprises a second pre-charge buffer configured to provide a charge to a second feedback capacitor in the second feedback loop during part of an integration phase of the integrator.

14. The switched-capacitor filter of claim 13, wherein the de-glitch circuit further comprises:
a switch in series with the second pre-charge buffer; and
a controller to close the switch during a first portion of the integration phase.

15. The switched-capacitor filter of claim 11, wherein the switched-capacitor filter is part of an integrated circuit on a die.

16. The switched-capacitor filter of claim 15, wherein the die includes a digital-to-analog converter (DAC) configured to provide an input signal to the integrator.

17. The switched-capacitor filter of claim 15, wherein the die is includes isolation circuitry configured to isolate the die from another die.

18. A switched-capacitor filter method that comprises:
receiving an integration phase signal;
in response to the integration phase signal, using a pre-charge buffer to charge a feedback capacitor during a first portion of an integration phase associated with the integration phase signal; and
coupling the feedback capacitor between input and output nodes of an integrator during a second portion of the integration phase.

19. The method of claim 18, wherein using the pre-charge buffer to charge a feedback capacitor during the first portion of an integration phase comprises controlling a pre-charge switch based on a first control signal, and wherein coupling the feedback capacitor between input and output nodes of the integrator during the second portion of the integration phase comprises controlling feedback loop switches based on a second control signal.

20. The method of claim 19, wherein the first and second control signals do not overlap.

21. The method of claim 20, wherein the integration phase signal is separate from the first and second control signals, and wherein the integration phase signal does not overlap with a sampling phase for a digital-to-analog converter (DAC) configured to provide an input signal to the integrator.
